(19) United States
(12) Patent Application Publication
(10) Pub. No.: US 2011/0030997 A1
(43) Pub. Date: Feb. 10, 2011

(54) FLEXIBLE PRINTED CIRCUIT BOARD

(75) Inventor: SHOU-KUO HSU, Tu-Cheng (TW)

Correspondence Address: Altis Law Group, Inc.;ATTN: Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/549,376

(22) Filed: Aug. 28, 2009

(30) Foreign Application Priority Data
Aug. 7, 2009 (CN) 200910305353.1

(51) Int. Cl. H05K 1/00

(52) U.S. Cl. 174/254

(57) ABSTRACT

A flexible printed circuit board (FPCB) includes a differential pair arranged in a signal layer and a ground sheet arranged in a ground layer. The differential pair includes a number of section pairs, each of which includes two sections arranged in two transmission lines of the differential pair respectively. The ground sheet is opposite to a space between the two transmission lines of the differential pair. The differential pair is equivalent to a filter which includes several capacitors and several inductors. Each of the plurality of section pairs can achieve a desired characteristic impedance by adjusting a first distance between each section and the ground sheet, and a second distance between the two sections of each of the plurality of section pairs.

### BACKGROUND

1. Technical Field

The present disclosure relates to printed circuit boards (PCBs), and particularly to a flexible printed circuit board (FPCB).

2. Description of Related Art

FPCBs are light, soft, thin, small, ductile, flexible and support high wiring density. FPCBs can be three-dimensionally wired and shaped according to space limitations. Flexible circuits are useful for electronic packages where flexibility, weight control and the like are important.

An FPCB may include a signal layer and a ground layer. Transmission lines may be arranged in the signal layer. Noise may be easily generated if the transmission lines are too close to the ground layer, which prevents the FPCB transmitting high speed signals. In addition, conventional FPCBs often have poor qualities for transmitting high speed signals because of failing to achieve required impedance.

### BRIEF DESCRIPTION OF THE DRAWINGS

FIG. 1 is a cross-sectional view of a flexible printed circuit board (FPCB) according to an embodiment of the present disclosure, wherein the FPCB includes a differential pair.

FIG. 2 is a top view of the FPCB of FIG. 1.

FIG. 3 is an equivalent circuit diagram of the differential pair of FIG. 1.

### DETAILED DESCRIPTION

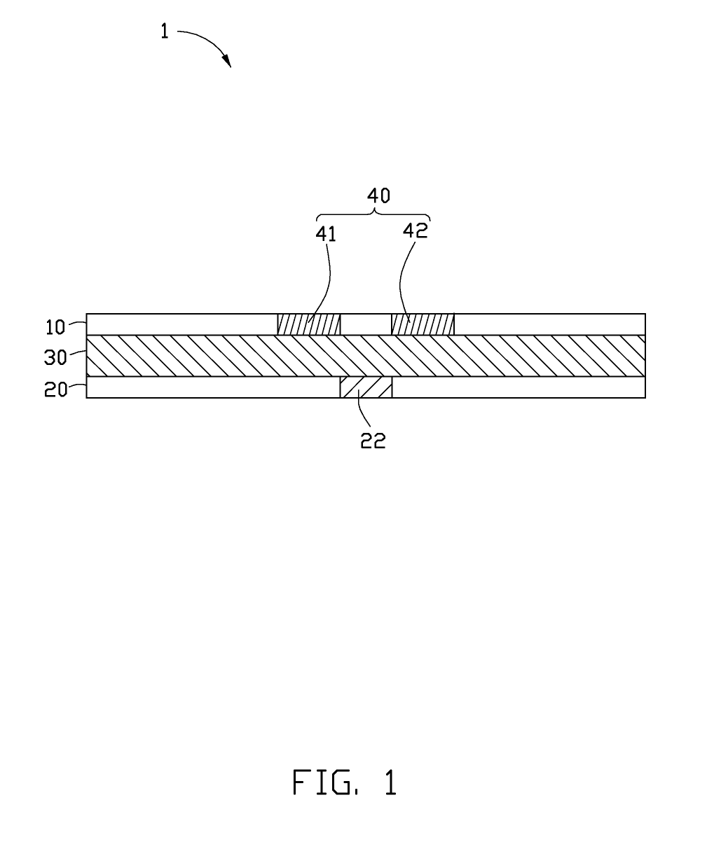

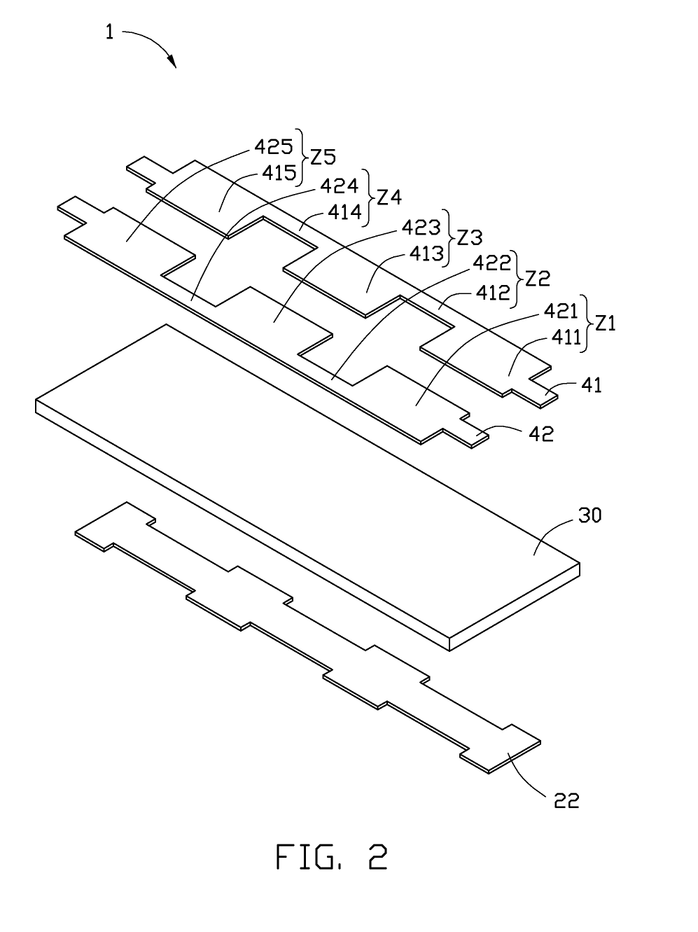

Referring to FIGS. 1 and 2, an embodiment of a flexible printed circuit board (FPCB) 1 includes a signal layer 10, and a ground layer 20 adjacent to the signal layer 10. An insulating layer 30 made of dielectric material 30 is arranged between the signal layer 10 and the ground layer 20. A differential pair 40 consisting of two transmission lines 41 and 42 is arranged in the signal layer 10.

A ground sheet 22 made of conductive material is arranged in the ground layer 20 opposite to a space between the transmission lines 41 and 42 of the differential pair 40. The ground sheet 22 is parallel to the transmission lines 41 and 42. A length of the ground sheet 22 is equal to a length of each of the transmission lines 41 and 42. Therefore, low characteristic impedance of the transmission lines 41 and 42 due to not enough distance between the differential pair 40 and the ground layer 20 can be prevented. A width of the ground sheet 22 is adjustable according to preference. In this embodiment, the ground sheet 22 is made of copper.

The differential pair 40 includes section pairs of aligned thick sections and section pairs of aligned thin sections arranged in an alternating manner along each of the transmission lines 41 and 42. Sections of each pair have symmetrical structures. The plurality of section pairs are formed between an input and an output of the differential pair 40. Sections are formed on the ground sheet 22 corresponding to the section pairs of the differential pair 40. Each section of the ground sheet 22 is opposite to a space between two corresponding sections of a section pair of the differential pair 40. Each section of the ground sheet 22 has the same length as the sections of a corresponding section pair. Every two adjacent sections of each of the transmission lines 41 and 42 are different in width. The differential pair 40 having the section pairs is equivalent to a low pass filter. A number of the section pairs of the differential pair 40 is predetermined depending on required specifications of the low pass filter. In this embodiment, there are five sections 411-415 defined in the transmission line 41, and five sections 421-425 defined in the transmission line 42, which form five section pairs Z1-Z5 respectively.

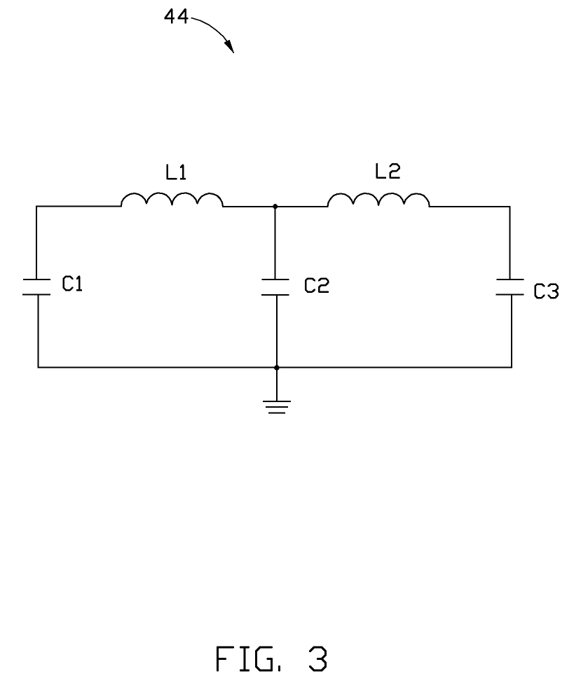

Referring to FIG. 3, the section pairs Z1, Z3, and Z5 are equivalent to three capacitors C1-C3 of a low pass filter 44. The section pairs Z2 and Z4 are equivalent to two inductors L1 and L2 of the low pass filter 44. The inductor L1 is connected between a first end of the capacitance C1 and a first end of the capacitance C2. The inductors L2 is connected between the first end of the capacitance C2 and a first end of the capacitance C3. A second end of each of the capacitances C1-C3 is grounded. A length of each section of each of the section pairs Z1, Z3, and Z5 is determined according to a first formula

$$C = \frac{l}{{Z}_{0} f {λ}_{g}} ,$$

and a length of each section of each of the section pairs Z2 and Z4 is determined according to a second formula

$$L = \frac{{Z}_{0} l}{f {λ}_{g}} .$$

Wherein C is a capacitance of the capacitor C1, C2 or C3 corresponding to the section pairs Z1, Z3, and Z5, L is an inductance of the inductor L1 or L2 corresponding to the section pairs Z2 and Z4, Z₀ is a desired characteristic impedance of the section pair Z1, Z2, Z3, Z4, or Z5, l is the length of each section of the section pair Z1, Z2, Z3, Z4, or Z5, f is a cut-off frequency of the low pass filter 44, λ_{g} is a wavelength of signals transmitted on the differential pair 40 under the cut-off frequency. Values of the cut-off frequency and wavelength of the signals under the cut-off frequency are fixed. The capacitances of the capacitances C1-C3, the inductances of the inductors L1-L2 are predetermined. Therefore, the length of each section of each of the section pairs Z1-Z5 can be determined according to the desired characteristic impedance of the section pairs Z1-Z5 correspondingly.

The desired characteristic impedance of each of the section pairs Z1-Z5 can be achieved by first simulating the FPCB 1 of FIG. 1 using a conventional simulation software, simulating the signal types to be transmitted through the transmission lines 41 and 42 and the desired characteristic impedance of each of the section pairs Z1-Z5, and adjusting a first distance between the two sections of each of the section pairs Z1-Z5 and a second distance from each section of each of the section pairs Z1-Z5 to the ground sheet 22, until the desired characteristic impedance of each of the section pairs Z1-Z5 is achieved. In this embodiment, the first distance between the two sections of each of the section pairs Z1-Z5 and the second distance from each of the sections 411-415 and 421-425 to the ground sheet 22 are adjusted by adjusting the width of each of the section 411-415 and 421-425 correspondingly. The second distance can also be adjusted by adjusting widths of each section of the ground sheet 22 correspondingly.

Low characteristic impedance of the transmission lines 41 and 42 due to not enough distance between the differential pair 40 and the ground sheet 22 can be prevented because the ground sheet 22 is arranged opposite to the space between the transmission lines 41 and 42. In addition, proper values of the first distance between the two sections of each of the section pairs Z1-Z5 and the second distance from each section of each of the section pairs Z1-Z5 to the ground sheet 22 may enable the FPCB 1 to achieve the desired characteristic impedance for each of the section pairs Z1-Z5 of the differential pair 40. Therefore, the FPCB 1 can transmit high speed signals with little noise.

The foregoing description of the exemplary embodiments of the disclosure has been presented only for the purposes of illustration and description and is not intended to be exhaustive or to limit the disclosure to the precise forms disclosed. Many modifications and variations are possible in light of the above everything. The embodiments were chosen and described in order to explain the principles of the disclosure and their practical application so as to enable others of ordinary skill in the art to utilize the disclosure and various embodiments and with various modifications as are suited to the particular use contemplated. Alternative embodiments will become apparent to those of ordinary skills in the art to which the present disclosure pertains without departing from its spirit and scope. Accordingly, the scope of the present disclosure is defined by the appended claims rather than the foregoing description and the exemplary embodiments described therein.

What is claimed is:

1. A flexible printed circuit board (FPCB) comprising:
a signal layer, wherein a differential pair comprising of two transmission lines is arranged in the signal layer; and
a ground layer adjacent to the signal layer, wherein a ground sheet made of conductive material is arranged in the ground layer; the ground sheet is opposite to a space between the two transmission lines of the differential pair, and is parallel to the two transmission lines; wherein
the differential pair comprises a plurality of section pairs, each of the plurality of section pairs comprises two sections arranged in the two transmission lines symmetrically, every two adjacent sections of each of the two transmission lines are different in width, each of the plurality of section pairs has a desired characteristic impedance relative to a predetermined first distance between each of the two sections of each of the plurality of section pairs and the ground sheet, and a predetermined second distance between the two sections of each of the plurality of section pairs.

2. The FPCB of claim 1, wherein the ground sheet is made of copper.

3. The FPCB of claim 1, wherein an insulating layer made of dielectric material is arranged between the signal layer and the ground layer.

4. The FPCB of claim 1, wherein every two adjacent section pairs are equivalent to a capacitor and an inductor of a low pass filter, each section of the section pairs which are equivalent to the capacitors has a greater width than each section of the section pairs which are equivalent to the inductors.

5. The FPCB of claim 4, wherein a length of each section of the section pairs which are equivalent to the capacitors is determined according to a first formula
$$C = \frac{l}{{Z}_{0} f {λ}_{g}} ,$$
and a length of each section of the section pairs which are equivalent to the inductors is determined according to a second formula
$$L = \frac{{Z}_{0} l}{f {λ}_{g}} ,$$
wherein C is a capacitance of each of the capacitors, L is an inductance of each of the inductors, Z₀ is the desired characteristic impedance of each of the plurality of section pairs, l is the length of each section of each of the plurality of section pairs, f is a cut-off frequency of the filter, λ_{g} is a wavelength of signals transmitted on the differential pair under the cut-off frequency.

6. A flexible printed circuit board comprising:
a signal layer, wherein a differential pair comprising of two transmission lines is arranged in the signal layer, the differential pair comprises a plurality of section pairs, each of the plurality of section pairs comprises two sections arranged in the two transmission lines respectively, the two sections of each of the plurality of section pairs have the same structures, every two adjacent section pairs are equivalent to a capacitor and an inductor respectively; and
a ground layer adjacent to the signal layer, wherein a ground sheet made of conductive material is arranged in the ground layer, a plurality of sections is defined in the ground sheet corresponding to the plurality of section pairs, each section of the ground sheet is opposite to a space between the two sections of the corresponding section pair;
wherein each of the plurality of section pairs has a desired characteristic impedance relative to a width of each section of the section pair, and a width of each of the plurality of sections of the ground sheet.

7. The flexible printed circuit board of claim 6, wherein a length of the ground sheet is equal to a length of each of the two transmission lines.
